(19) United States
(12) Patent Application Publication
(10) Pub. No.: US 2010/0164358 A1
(43) Pub. Date: Jul. 1, 2010

(54) FILTER FOR PLASMA DISPLAY AND FABRICATING METHOD THEREOF

(75) Inventors: Jinyoung Lee, Yongin-si (KR); Sungyong Lee, Yongin-si (KR); Jaeyoung Park, Yongin-si (KR); Jaehyung Kim, Yongin-si (KR); Dohyukl Kwon, Yongin-si (KR)

Correspondence Address: STEIN MCEWEN, LLP, 1400 EYE STREET, NW, SUITE 300, WASHINGTON, DC, 20005, US

(73) Assignee: Samsung SDI Co., Ltd., Suwon-si (KR)

(21) Appl. No.: 12/641,544

(22) Filed: Dec. 18, 2009

(30) Foreign Application Priority Data
Dec. 30, 2008 (KR) 10-2008-0136878

(51) Int. Cl. H01J 1/52; B05D 5/12; H05K 9/00

(52) U.S. Cl. 313/313; 427/58; 427/126.3; 174/392

(57) ABSTRACT

A filter for a plasma display includes an electromagnetic interference shielding mesh formed on a substrate to shield electromagnetic waves and a hard coating layer made of inorganic material formed on the electromagnetic interference shielding mesh. The filter is fabricated so as to provide a reduced thickness of a plasma display, to prevent cracks from being generated on surfaces of the mesh and to reduce manufacturing costs.

### CROSS-REFERENCE TO RELATED APPLICATIONS

This application claims the benefit of Korean Patent Application No. 10-2008-0136878 filed on Dec. 30, 2008 in the Korean Intellectual Property Office, the disclosure of which is incorporated herein by reference.

### BACKGROUND OF THE INVENTION

1. Field of the Invention

Aspects of the present invention relate to a filter for a plasma display and a fabricating method thereof.

2. Description of the Related Art

An electromagnetic interference (EMI) film for a plasma display is typically fabricated in a method by which copper is plated onto or thinly bonded to a substrate of polyethylene terephthalate (PET), which is etched in the form of a mesh, after which the etched copper is oxidized black. However, the mesh lines of the EMI shield film typically have a thickness of about 10 μm and have a wide prominence (that is, the mesh lines prominently protrude from the surface of the substrate).

Since it is difficult to make the mesh into a filter due to the protrusion of the mesh lines, a color compensating layer or an antireflective film is additionally formed on the mesh to form the EMI shield film. However, the addition of the color compensating layer and the antireflective film brings an increase of time and costs for processing.

### SUMMARY OF THE INVENTION

Aspects of the present invention provide a filter for a plasma display allowing reduction of thickness so as to achieve a slim plasma display, to restrain cracks from being generated on surfaces of a mesh, and to reduce manufacturing costs thereof, and a fabricating method thereof.

In accordance with an embodiment of the present invention, there is provided a film for a plasma display, comprising: an electromagnetic interference shielding mesh formed on a substrate and shielding electromagnetic waves; and a first hard coating layer formed on the electromagnetic interference shielding mesh and made of inorganic material.

According to an aspect of the present invention, the electromagnetic interference shielding mesh has a line width of 5 μm to 50 μm.

According to an aspect of the present invention, the electromagnetic interference shielding mesh has a pitch of 50 μm to 500 μm.

According to an aspect of the present invention, the electromagnetic interference shielding mesh has a thickness of 2 μm to 10 μm.

According to an aspect of the present invention, the electromagnetic interference shielding mesh comprises a mixture of at least one black material selected from a the group consisting of carbon black, cobalt oxide, and ruthenium oxide and at least one conductive material selected from the group consisting of copper (Cu), silver (Ag), nickel (Ni), aluminum (Al), and ruthenium (Ru).

According to an aspect of the present invention, the hard coating layer comprises at least one selected from a group of silicon oxide (SiO₂), titanium oxide (TiO₂), zirconium oxide (ZrO₂) and combinations thereof.

According to an aspect of the present invention, the first hard coating layer further comprises a color compensating pigment and/or a near infrared ray shielding pigment mixed with the inorganic material.

According to an aspect of the present invention, the film further comprises an additional hard coating layer formed on the hard coating layer, having a refractive index different from that of the hard coating layer, and preventing reflection.

According to an aspect of the present invention, the first hard coating layer is formed by coating the inorganic material on the electromagnetic interference shielding mesh in the form of paste by at least one method selected from a group of slit coating, spraying, printing, and spin coating, and baking at 250 degrees Celsius (° C.) to 500° C.

According to an aspect of the present invention, the first hard coating layer overcoats a height difference between the bottom and the top of the electromagnetic interference shielding mesh.

In accordance with an embodiment of the present invention, there is provided a method of fabricating a film for a plasma display, comprising: forming an electromagnetic interference shielding mesh on a transparent substrate; coating an inorganic material onto the electromagnetic interference shielding mesh; and baking the inorganic material to form a first hard coating layer.

According to an aspect of the present invention, the transparent substrate comprises at least one selected from an upper substrate of a plasma display panel and glass of a plasma display set.

According to an aspect of the present invention, the formation of the electromagnetic interference shielding mesh is performed by at least one method selected from a group of offset printing, inkjet printing, and screen printing.

In the formation of the electromagnetic interference shielding mesh according to an aspect of the present invention, the electromagnetic interference shielding mesh is made by mixing at least one black material selected from the group consisting of carbon black, cobalt oxide, and ruthenium oxide with at least one conductive material selected from the group consisting of copper (Cu), silver (Ag), nickel (Ni), aluminum (Al), and ruthenium (Ru).

In the coating of the inorganic material according to an aspect of the present invention, the hard coating layer is made of at least one selected from the group consisting of silicon oxide (SiO₂), titanium oxide (TiO₂), and zirconium oxide (ZrO₂) and combinations thereof.

In the coating of the inorganic material according to an aspect of the present invention, the inorganic material is further coated with at least one selected from a group color compensating pigment, near infrared ray shielding pigment, and a combination thereof.

In the baking of the inorganic material according to an aspect of the present invention, the inorganic material is baked at 250° C. to 500° C.

According to an aspect of the present invention, the fabricating method further comprises: coating an additional inorganic material on the first hard coating layer after the baking of the inorganic material; and baking the additional inorganic material to form an additional hard coating layer.

In the coating of the additional inorganic material, the additional inorganic material is formed by coating an additional inorganic material having a refractive index different from that of the first hard coating layer, wherein the additional inorganic material is selected from the group consisting of silicon oxide (SiO₂), titanium oxide (TiO₂), zinc oxide (ZnO), and zirconium oxide (ZrO₂).

In the baking of the additional inorganic material, the additional inorganic material is baked at 250° C. to 500° C.

According to an embodiment of the present invention, there is provided a plasma display comprising a plasma display set including a plasma display panel; and a filter comprising: an electromagnetic interference shielding mesh that shields electromagnetic waves and that is formed on at least one of an upper substrate of the plasma display panel and a glass of the plasma display set; and a first hard coating layer formed on the electromagnetic interference shielding mesh and made of inorganic material.

In the filter for a plasma display according to aspects of the present invention, the first hard coating layer is formed with inorganic material on the EMI shield mesh to form the first hard coating layer such that the first hard coating layer exhibits a hard coating function, and as a result time and costs for the manufacturing can be reduced and cracks can be restricted from being generated during the baking of the first hard coating layer.

Moreover, since the color compensating pigment and the near infrared ray shielding pigment are added into the first hard coating layer, the first hard coating layer performs color compensation and infrared ray shielding so that time and costs for manufacturing a plasma display device can be reduced and a thin plasma display can be achieved.

In the filter for a plasma display according to aspects of the present invention, the additional hard coating layer is formed on the first hard coating layer such that the first hard coating layer and the additional hard coating layer perform a reflection preventing function. Thus, light emitted from the lower PDP to display an image is prevented from being reflected and the brightness is enhanced.

Additional aspects and/or advantages of the invention will be set forth in part in the description which follows and, in part, will be obvious from the description, or may be learned by practice of the invention.

### BRIEF DESCRIPTION OF THE DRAWINGS

These and/or other aspects and advantages of the invention will become apparent and more readily appreciated from the following description of the embodiments, taken in conjunction with the accompanying drawings of which:

FIG. 1A is a perspective view illustrating a filter for a plasma display according to an embodiment of the present invention;

FIG. 1B is a perspective view illustrating an electromagnetic interference shielding mesh applied to the filter for a plasma display according to the embodiment of the present invention;

FIG. 2 is a perspective view illustrating a filter for a plasma display according to another embodiment of the present invention;

FIG. 3 is a flowchart illustrating a fabricating method of a filter for a plasma display according to an embodiment of the present invention;

FIGS. 4A to 4D are perspective views illustrating the fabricating method of a filter for a plasma display according to the embodiment of the present invention; and

FIG. 5 is a flowchart illustrating a fabricating method of a filter for a plasma display.

### DETAILED DESCRIPTION OF THE EMBODIMENTS

Reference will now be made in detail to the present embodiments of the present invention, examples of which are illustrated in the accompanying drawings, wherein like reference numerals refer to the like elements throughout. The embodiments are described below in order to explain the present invention by referring to the figures.

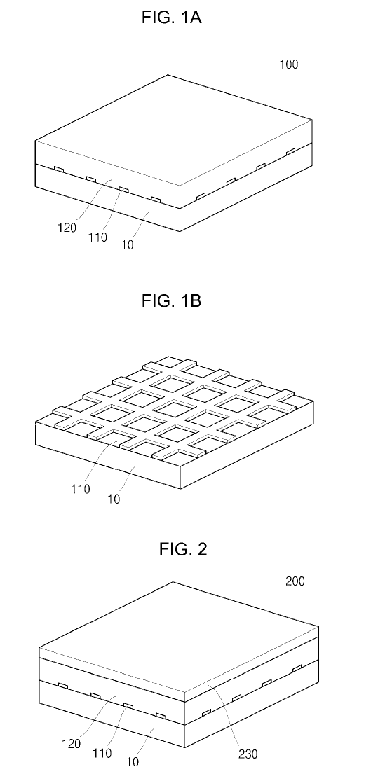

Hereinafter, a filter 100 of a plasma display according to an embodiment of the present invention will be described. FIG. 1A is a perspective view illustrating the filter 100 and FIG. 1B is a perspective view illustrating an electromagnetic interference shielding mesh 110 applied to the filter 100. In particular, referring to FIGS. 1A and 1B, the filter 100 includes an EMI shielding mesh 110 formed on a substrate 10 and a hard coating layer 120 formed on the EMI shielding mesh 110. Herein, the term “formed on” is used with the same meaning as “located on” or “disposed on” and is not meant to be limiting regarding any particular fabrication process. Also, herein, the hard coating layer 120 may be referred to as the “first hard coating layer 120” to distinguish the optional additional hard coating layer 230 formed according to another embodiment as described below. However, the use of the term “first hard coating layer” is not intended to imply or require that a second or additional hard coating layer must be present.

The substrate 10 is made of a transparent material. The substrate 10 may be at least one selected from an upper substrate of a plasma display panel and a glass of a plasma display set. When the substrate 10 is the upper substrate of the plasma display panel, the plasma display set can be thinner than if the substrate 10 is a glass of the plasma display set. The substrate 10 may be made of general glass, reinforced glass, or an equivalent thereof, but is not limited thereto.

The EMI shielding mesh 110 is formed on the substrate 10. The EMI shielding mesh 110 includes a plurality of horizontal lines and a plurality of vertical lines perpendicular to the horizontal lines to form a mesh shape. The EMI shielding mesh 110 shields electromagnetic waves generated from the plasma display panel (PDP). The EMI shielding mesh 110 may also block incident light entering the PDP.

To this end, the EMI shielding mesh 110 comprises a mixture of at least one black material selected from the group consisting of carbon black, cobalt oxide, and ruthenium oxide and a conductive material selected from the group consisting of copper (Cu), silver (Ag), nickel (Ni), aluminum (Al), and ruthenium (Ru). The EMI shielding mesh 110 may be formed by at least one method selected from a slit coating, spraying, printing, and spin coating.

The EMI shielding mesh 110 may have a line width of 5 μm to 50 μm. When the line width of the EMI shielding mesh 110 is less than 5 μm, an area and an angular range in which the electromagnetic waves and incident lights are shielded are decreased and as a result, the electromagnetic waves and the incident lights are not properly shielded. On the other hand, when the line width of the EMI shielding mesh 110 is greater than 50 μm, the aperture ratio is so decreased that brightness is also decreased.

The EMI shielding mesh 110 may have a pitch of 100 μm to 500 μm. When the pitch of the EMI shielding mesh 110 is less than 100 μm, the aperture ratio is decreased and brightness is also decreased. When the pitch of the EMI shielding mesh 110 is greater than 500 μm, the pitch is wider than the line width and the shield efficiency with respect to electromagnetic waves and incident light are also decreased.

The EMI shielding mesh 110 may have a thickness of 2 μm to 10 μm. Herein, “thickness” of the EMI shielding mesh 110 is in a direction perpendicular to the substrate 10. When the thickness of the EMI shielding mesh 110 is less than 2 μm, the shielding efficiency with respect to electromagnetic waves and incident light are decreased. When the thickness of the EMI shielding mesh 110 is greater than 10 μm, a height difference between the bottom and the top of the EMI shielding mesh 110 is increased. Thus, the hard coating layer 120 formed on the EMI shielding mesh 110 becomes thicker and overall thickness of the PDP is also increased.

The hard coating layer 120 is formed on the EMI shielding mesh 110 to cover the EMI shielding mesh 110. The hard coating layer 120 overcoats the EMI shielding mesh 110 to correct the height difference of the EMI shielding mesh 110. Thus, irregularities of shielding the electromagnetic waves and incident light and the brightness caused by the height difference can be prevented. The hard coating layer 120 is formed of a single layer such that the number of layers forming the filter 100 can be reduced and as a result, time and costs for the manufacturing process can be also reduced.

The hard coating layer 120 is made of at least one inorganic material selected from the group consisting of silicon oxide (SiO₂), titanium oxide (TiO₂), and a zirconium (ZrO₂). The hard coating layer 120 may have a transmittance of about 90% so that the plasma display panel transmits light well, and does not decrease the brightness of light transmitted therethrough when the hard coating layer 120 is applied to the filter 100 for a plasma display. Moreover, since inorganic material has a hardness higher than that of organic material, the hard coating layer 120 may be formed with a thickness thinner than that of a conventional hard coating layer formed with organic material. Thus, the hard coating layer 120 prevents cracks from being generated during the baking used in the formation of the hard coating layer 120. The hard coating layer 120 may be coated onto the EMI shielding mesh in the form of paste by at least one method selected from the group consisting of slit coating, spraying, printing, and spin coating and is baked at 250° C. to 500° C.

In the hard coating layer 120, the inorganic material may include a color compensating pigment and/or a near infrared rays shield pigment. Thus, in the hard coating layer 120, a hard coating, color compensation, and near infrared ray shielding function may be combined into a single layer without the need for an additional color compensation layer or near infrared ray shielding layer. Accordingly, when the filter 100 is applied to a plasma display panel, the thickness of the PDP can be reduced and time and costs of manufacturing the same can be also reduced in comparison to when a separate color compensating layer and near infrared ray shielding layer are formed.

By forming the hard coating layer 120 with an inorganic material on the EMI shielding mesh 110, time and costs for the manufacturing can be reduced and cracks can be restricted from being generated during the baking of the hard coating layer 120. Since the color compensating pigment and the near infrared ray shielding pigment are added into the hard coating layer 120, the hard coating layer 120 also performs color compensation and infrared ray shielding so that time and costs for manufacturing a plasma display device can be reduced and a thin plasma display can be achieved.

Hereinafter, a filter 200 for a plasma display according to another embodiment of the present invention will be described.

FIG. 2 is a perspective view illustrating the filter 200 for a plasma display according to another embodiment of the present invention. The same reference numerals are assigned to the same or like elements and portions as those in the former embodiment, and differences from the former embodiment will be described.

As illustrated in FIG. 2, the filter 200 for a plasma display according to another embodiment of the present invention includes an electromagnetic inference (EMI) shielding mesh 110 formed on a substrate 10, a first hard coating layer 120 formed on the EMI shielding mesh 110, and an additional hard coating layer 230 formed on the hard coating layer 120.

The additional hard coating layer 230 performs a reflection preventing function together with the first hard coating layer 120. In other words, the additional hard coating layer 230 and the first hard coating layer 120 do not reflect light emitted from the PDP to display an image but transmit the same. To this end, the additional hard coating layer 230 may be made of inorganic material having a refractive index different from that of the first hard coating layer 120. In particular, the additional hard coating layer 230 may be made of at least one inorganic material having a refractive index different from that of the first hard coating layer 120 and may be selected from the group consisting of silicon oxide (SiO₂), titanium oxide (TiO₂), and zirconium oxide (ZrO₂).

The additional hard coating layer 230 is formed on the first hard coating layer 120 such that the first hard coating layer 120 and the additional hard coating layer 230 perform a reflection preventing function. Thus, light emitted from the PDP to display an image is prevented from being reflected and the brightness is enhanced.

Hereinafter, a fabricating method of a filter 100 of a plasma display according to an embodiment of the present invention will be described.

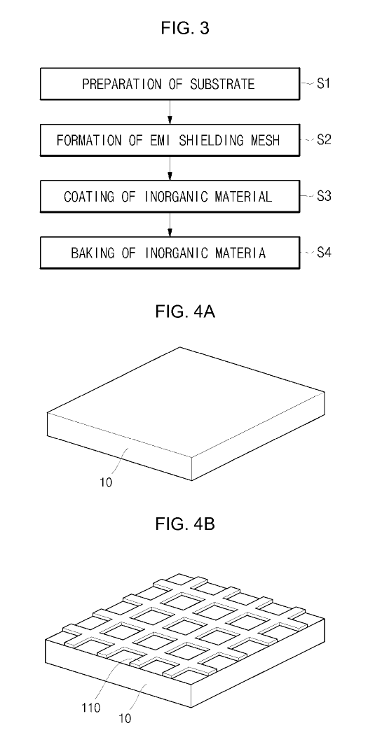

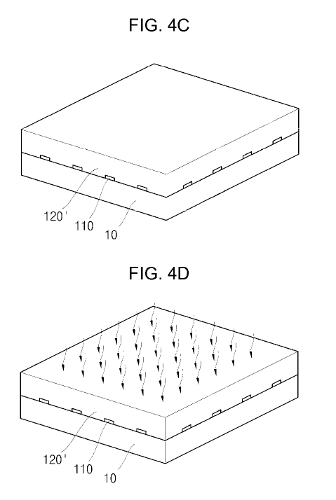

FIG. 3 is a flowchart illustrating a fabricating method of the filter 100 of a plasma display according to the embodiment of the present invention. FIGS. 4A to 4D are views sequentially illustrating the fabricating method of the filter 100 according to the embodiment of the present invention.

Referring to FIG. 3, the fabricating method of the filter 100 includes preparing a substrate (S1), forming an electromagnetic interference (EMI) shielding mesh (S2), forming an inorganic material coating (S3), and baking the substrate having the EMI shielding mesh and the inorganic material coating formed thereon (S4). Hereinafter, the respective operations in FIG. 3 will be described with reference to FIGS. 4A to 4D.

Referring to FIGS. 3 and 4A, the preparing of the substrate (S1) is performed to prepare a substrate 10 that transmits light. The substrate 10 may be at least one selected from an upper substrate of a plasma display panel and glass of a plasma display set. The fact that the thin plasma display set can be achieved when the substrate 10 is the upper substrate of the PDP has been already described.

Referring to FIGS. 3 and 4B, the forming of the EMI shielding mesh (S2) is performed to form the EMI shielding mesh 110 on the substrate 10. The EMI shielding mesh 110 includes a plurality of horizontal lines and a plurality of vertical lines perpendicular to the horizontal lines, and is formed using at least one method selected from off-set printing, inkjet printing, and screen printing. The EMI shielding mesh 110 is made by mixing at least one black material selected from the group consisting of carbon black, cobalt oxide, and ruthenium oxide with at least one conductive material selected the group consisting of copper (Cu), silver (Ag), nickel (Ni), aluminum (Al), and ruthenium (Ru).

Referring to FIGS. 3 and 4C, the forming of the inorganic material coating (S3) is performed to coat an inorganic material 120′ onto the EMI shielding mesh 110. The inorganic material 120′ may be made of at least one selected from the group consisting of silicon oxide (SiO₂), titanium oxide (TiO₂), zinc oxide (ZnO), and zirconium oxide (ZrO₂) or a combination thereof. If it is desired to add the color compensating function and/or the near infrared ray shielding function, at least one selected from a color compensating pigment and a near infrared ray shielding pigment may be mixed with the inorganic material 120′ and coated onto the EMI shielding mesh 110.

Referring to FIGS. 3 and 4D, the baking of the substrate having the EMI shielding mesh and the inorganic material coating formed thereon (S4) is performed to form the hard coating layer 120 by baking the inorganic material 120′ at 250° C. to 500° C. When the baking temperature is lower than 250° C., it takes long time to bake the inorganic material 120′ thereby increasing the overall fabricating time. Moreover, when the baking temperature exceeds 500° C., there is a possibility of cracks being generated in the hard coating layer 120.

Hereinafter, a fabricating method of a filter 200 for a plasma display according to another embodiment will be described.

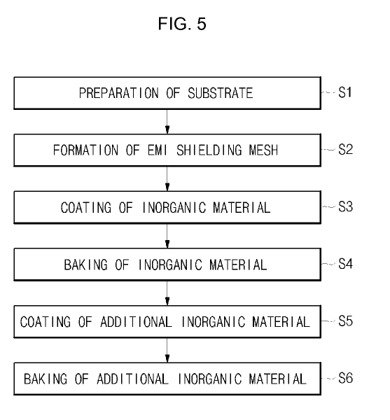

FIG. 5 is a flowchart illustrating the fabricating method of the filter 200 for a plasma display according to another embodiment of the present invention.

Referring to FIG. 5, the fabricating method of a filter 200 for a plasma display according to another embodiment of the present invention further includes forming an additional coating of inorganic material (S5) and an additional baking (S6) in addition to preparing a substrate (S1), forming an electromagnetic interference (EMI) shielding mesh (S2), forming an inorganic material coating (S3), and baking (S4).

In the forming of an additional inorganic material coating (S5), an additional inorganic material is coated onto the first hard coating layer 120. The additional inorganic material is made of at least one inorganic material having a refractive index different from that of the first hard coating layer 120, selected from the group consisting of silicon oxide (SiO₂), titanium oxide (TiO₂), and zirconium oxide (ZrO₂). The additional inorganic material coating may be performed by a method selected from the group of slit coating, spraying, printing, and spin coating.

After being coated onto the first hard coating layer 120, the additional inorganic material is baked to form the additional hard coating layer 230. The additional baking (S6) may be performed at 250° C. to 500° C., as with the baking (S4) to form the first hard coating layer 120. Thus, the additional hard coating layer 230 is formed using the additional inorganic material so that the additional hard coating layer 230 and the first hard coating layer 120 do not reflect light emitted from the lower PDP to display an image but instead, transmit the same.

Although a few embodiments of the present invention have been shown and described, it would be appreciated by those skilled in the art that changes may be made in this embodiment without departing from the principles and spirit of the invention, the scope of which is defined in the claims and their equivalents.

What is claimed is:

1. A filter for a plasma display comprising:
an electromagnetic interference shielding mesh formed on a substrate to shield electromagnetic waves; and
a first hard coating layer formed on the electromagnetic interference shielding mesh and made of inorganic material.

2. The filter for a plasma display of claim 1, wherein the electromagnetic interference shielding mesh has a line width of 5 μm to 50 μm.

3. The filter for a plasma display of claim 1, wherein the electromagnetic interference shielding mesh has a pitch of 50 μm to 500 μm.

4. The filter for a plasma display of claim 1, wherein the electromagnetic interference shielding mesh has a thickness of 2 μm to 10 μm.

5. The filter for a plasma display of claim 1, wherein the electromagnetic interference shielding mesh comprises a mixture of at least one black material selected from the group consisting of carbon black, cobalt oxide, and ruthenium oxide and at least one conductive material selected from the group consisting of copper (Cu), silver (Ag), nickel (Ni), aluminum (Al), and ruthenium (Ru).

6. The filter for a plasma display of claim 1, wherein the hard coating layer comprises at least one selected from a group of silicon oxide (SiO₂), titanium oxide (TiO₂), zirconium oxide (ZrO₂) and combinations thereof.

7. The filter for a plasma display of claim 1, wherein the first hard coating layer further comprises a color compensating pigment and/or a near infrared ray shielding pigment mixed with the inorganic material.

8. The filter for a plasma display of claim 1, further comprising an additional hard coating layer formed on the first hard coating layer, having a refractive index different from that of the first hard coating layer.

9. The filter for a plasma display of claim 1, wherein the first hard coating layer overcoats a height difference between the bottom and the top of the electromagnetic interference shielding mesh.

10. A fabricating method of a filter for a plasma display, the fabricating method comprising:
forming an electromagnetic interference shielding mesh on a transparent substrate;
coating an inorganic material onto the electromagnetic interference shielding mesh; and
baking the inorganic material to form a first hard coating layer.

11. The fabricating method of claim 10, wherein the substrate comprises at least one of an upper substrate of a plasma display panel and a glass of a plasma display set.

12. The fabricating method of claim 10, wherein the formation of the electromagnetic interference shielding mesh is performed by at least one method selected from the group consisting of offset printing, inkjet printing, and screen printing.

13. The fabricating method of claim 10, wherein the electromagnetic interference shielding mesh is formed by mixing at least one black material selected from the group consisting of carbon black, cobalt oxide, and ruthenium oxide with at least one conductive material selected from the group consisting of copper (Cu), silver (Ag), nickel (Ni), aluminum (Al), and ruthenium (Ru).

14. The fabricating method of claim 10, wherein the inorganic material that is coated onto the electromagnetic interference shielding mesh and baked to form the first hard coating layer comprises at least one selected from the group consisting of silicon oxide (SiO₂), titanium oxide (TiO₂), zirconium oxide (ZrO₂) and combinations thereof.

15. The fabricating method of claim 10, wherein at least one selected from a group consisting of color compensating pigment, near infrared ray shielding pigment, and a combination thereof is combined with the inorganic material that is coated onto the electromagnetic interference shielding mesh.

16. The fabricating method of claim 10, further comprising:
coating an additional inorganic material onto the first hard coating layer after the baking of the inorganic material; and
baking the additional inorganic material to form an additional hard coating layer.

17. The fabricating method of claim 16, wherein the additional inorganic material has a refractive index different from the organic material of the hard coating layer and is selected from the group consisting of silicon oxide (SiO₂), titanium oxide (TiO₂), zinc oxide (ZnO), and zirconium oxide (ZrO₂).

18. A plasma display comprising:
a plasma display set including a plasma display panel; and
a filter comprising:
an electromagnetic interference shielding mesh that shields electromagnetic waves and that is formed on at least one of an upper substrate of the plasma display panel and a glass of the plasma display set; and
a first hard coating layer formed on the electromagnetic interference shielding mesh and made of inorganic material.
